(19) United States
(12) Patent Application Publication
(10) Pub. No.: US 2024/0342911 A1
(43) Pub. Date: Oct. 17, 2024

(54) SUBSTRATE TRANSPORT APPARATUS AND ABNORMALITY DETECTION METHOD

(71) Applicant: Panasonic Intellectual Property Management Co., Ltd., Osaka (JP)

(72) Inventors: Takashi SASASHIGE, OSAKA (JP); Ryo OTSUJI, KYOTO (JP)

(21) Appl. No.: 18/588,455

(22) Filed: Feb. 27, 2024

(30) Foreign Application Priority Data
Apr. 17, 2023 (JP) 2023-067243

(51) Int. Cl. B25J 9/16; B25J 11/00

(52) U.S. Cl. CPC B25J 9/1674; B25J 9/1653; B25J 11/0095

(57) ABSTRACT

The disclosed substrate transport apparatus includes a substrate storage portion that stores a substrate, a measurement portion including a rotation stage on which the substrate is to be placed and a sensor that measures the position of the outer edge of the substrate on the rotation stage, a transport portion that takes out a substrate from the substrate storage portion and places the substrate on the rotation stage, and an abnormality detection unit that detects an abnormality in the transport portion. The abnormality detection unit detects an abnormality in the transport portion based on measurement data acquired by the sensor while the rotation stage is rotated in the measurement portion.

### CROSS REFERENCE TO RELATED APPLICATION

The present application is based on and claims priority under 35 U.S.C. § 119 with respect to the Japanese Patent Application No. 2023-067243 filed on Apr. 17, 2023, of which entire content is incorporated herein by reference into the present application.

### TECHNICAL FIELD

The present disclosure relates to a substrate transport apparatus and an abnormality detection method.

### BACKGROUND

Conventionally, a substrate processing apparatus is known that can transport a substrate to be processed and correct positional deviation of the substrate during transport (e.g., JP H10-135301). The substrate processing apparatus of JP H10-135301 includes two transport portions that transport the substrate, and an alignment portion disposed therebetween, and the alignment portion is configured to rotate the substrate and continuously measure the position of the outer edge of the rotating substrate, and to correct positional deviation of the substrate based on obtained measurement data.

### SUMMARY

Incidentally, if an abnormality occurs in the transport portion, not only will it be necessary to frequently perform the above-described positional deviation correction, but in some cases, there is a risk that a positional deviation that cannot be corrected through the positional deviation correction will occur. In view of this, it is conceivable to separately provide a device (e.g., a sensor) for detecting an abnormality in the transport portion, but this would lead to an increase in the cost of the substrate processing apparatus. In such a situation, one of the objects of the present disclosure is to detect an abnormality in the transport portion with high accuracy without adding a device.

One aspect of the present disclosure relates to a substrate transport apparatus. The substrate transport apparatus includes: a substrate storage portion configured to store a substrate; a measurement portion including a rotation stage on which the substrate is to be placed and a sensor configured to measure a position of an outer edge of the substrate on the rotation stage; a transport portion configured to take out the substrate from the substrate storage portion and place the substrate on the rotation stage; and an abnormality detection unit configured to detect an abnormality in the transport portion, in which the abnormality detection unit detects an abnormality in the transport portion based on measurement data acquired by the sensor while the rotation stage is rotated in the measurement portion.

Another aspect of the present disclosure relates to an abnormality detection method. The abnormality detection method is an abnormality detection method for detecting an abnormality in a transport portion of a substrate transport apparatus including: a substrate storage portion configured to store a substrate; a measurement portion including a rotation stage on which the substrate is to be placed and a sensor configured to measure a position of an outer edge of the substrate on the rotation stage; and the transport portion configured to take out the substrate from the substrate storage portion and place the substrate on the rotation stage, the method including an abnormality detection step of detecting an abnormality in the transport portion based on measurement data acquired by the sensor while the rotation stage is rotated in the measurement portion.

According to the present disclosure, an abnormality in the transport portion can be detected with high accuracy without adding a device.

### BRIEF DESCRIPTION OF THE DRAWINGS

FIG. 1 is a plan view schematically showing an example of a substrate transport apparatus according to the present disclosure.

FIG. 2 is a side view schematically showing a measurement portion.

FIG. 3 is a plan view schematically showing the measurement portion and a substrate, in which the substrate with no positional deviation is indicated by a broken line, and the substrate with positional deviation is indicated by a solid line.

FIG. 4 is a graph showing an example of measurement data acquired by the measurement portion.

FIG. 5 is a graph showing an example of chronological data used for abnormality detection in the transport portion in Embodiment 1.

FIG. 6 is a graph showing an example of chronological data used for abnormality detection in the transport portion in Embodiment 2.

FIG. 7 is a graph showing an example of chronological data used for abnormality detection in the transport portion in Embodiment 3.

### DETAILED DESCRIPTION

Embodiments of a substrate transport apparatus and an abnormality detection method according to the present disclosure will be described below using examples. However, the present disclosure is not limited to the examples described below. In the following description, specific numerical values and materials are illustrated in some cases, but other numerical values and materials may also be applied as long as the effects of the present disclosure can be obtained.

### Substrate Transport Apparatus

The substrate transport apparatus according to the present disclosure may be an apparatus that carries a substrate into and out of a substrate processing apparatus such as a plasma treatment apparatus (e.g., a plasma etching apparatus, a plasma dicer, a plasma cleaner). The substrate transport apparatus according to the present disclosure includes a substrate storage portion, a measurement portion, a transport portion, and an abnormality detection unit.

The substrate storage portion stores a substrate. The substrate storage portion may store a plurality of substrates. The substrate may be a circular substrate. The substrate may be a semiconductor substrate, and may have a plurality of element regions and division regions defining the plurality of element regions. Such a substrate can be diced into a plurality of element chips corresponding to each element region by etching the division regions using a plasma treatment apparatus.

The measurement portion includes a rotation stage and a sensor. A substrate is placed on the rotation stage. The sensor measures the position of an outer edge of the substrate on the rotation stage. The rotation stage may be driven to rotate about a vertical axis by a driving means such as a rotation motor. The sensor may measure the position of the outer edge of the substrate in a non-contact manner, for example, by optical means.

The transport portion takes out the substrate from the substrate storage portion and places the substrate on the rotation stage. In other words, the transport portion transports the substrate from the substrate storage portion to the measurement portion. The transport portion may further take out the substrate from the measurement portion and transport the substrate to the substrate processing apparatus. The transport portion may transport the processed substrate to the substrate storage portion. The transport portion may include, for example, a transport robot having an end effector capable of holding the substrate.

The abnormality detection unit detects an abnormality in the transport portion. The abnormality detection unit may be included in a control unit that controls the substrate transport apparatus. The control unit may include an arithmetic device and a storage device storing a program that is executable by the arithmetic device.

The abnormality detection unit according to the present disclosure detects an abnormality in the transport portion based on measurement data acquired by the sensor while the rotation stage is rotated in the measurement portion. Here, such measurement data can be used to correct positional deviation of the substrate, and therefore is data that is acquired in a general substrate transport apparatus, and the abnormality detection unit uses this measurement data to detect an abnormality in the transport portion. That is, an abnormality in the transport portion is detected by effectively utilizing measurement data from a device (i.e., the measurement portion) conventionally provided for correcting positional deviation of the substrate. Accordingly, there is no need to add a device to detect an abnormality in the transport portion.

Also, the measurement data acquired by the sensor while the rotation stage is rotating, that is, the measurement data relating to a change in the position of the outer edge of the rotating substrate, is sinusoidal curve data having a predetermined amplitude (substantially zero if there is no positional deviation of the substrate). Here, for example, if foreign matter is attached to the outer edge of the substrate, such curve data may include singular points having discontinuous values. However, on the premise that the measurement data is sinusoidal curve data, highly accurate abnormality detection by the abnormality detection unit can be performed after such singular points are removed. Such processing is possible by continuously measuring the position of the outer edge of the substrate in the peripheral direction, as in the present disclosure.

If a value related to the amplitude of the measurement data exceeds a first threshold value, the abnormality detection unit may determine that there is an abnormality in the transport portion. The amplitude of the measurement data may be the amplitude of the sinusoidal curve data. The value related to the amplitude may be the value of the amplitude, a product of the value of the amplitude and a predetermined value, an output value of a predetermined function using the value of the amplitude as a variable, a moving average of any of these values, or the absolute value of the difference between any of these values and the moving average. The first threshold value may be a predetermined positive value set relative to the value related to the amplitude.

If a trend of increasing is observed in the value related to the amplitude of the measurement data, the abnormality detection unit may determine that there is an abnormality in the transport portion. This determination method is based on the new knowledge that when an abnormality occurs in a drive mechanism included in the transport portion or the like, a trend of increasing is observed in the value related to the amplitude of the measurement data. Even if the value related to the amplitude of the measurement data does not exceed the first threshold value, an abnormality in the transport portion can be detected by checking whether or not there is such a trend of increasing.

The value related to the amplitude may be the amount of deviation of the substrate from the rotation center of the rotation stage, which is determined based on the amplitude. The amount of deviation of the substrate from the rotation center of the rotation stage may be the horizontal distance between the central axis of the substrate and the rotation center of the rotation stage. Note that since the amplitude is usually twice as large as the amount of deviation, it can be said that the amount of deviation is the product of the value of the amplitude and 0.5, which serves as the predetermined value.

### Abnormality Detection Method

The abnormality detection method according to the present disclosure can be executed, for example, in the above-described substrate transport apparatus, and includes an abnormality detection step. In the abnormality detection step, an abnormality in the transport portion is detected based on measurement data acquired by the sensor while the rotation stage is rotated in the measurement portion. The constituent element that mainly executes the abnormality detection step may be the control unit (or the abnormality detection unit) provided in the substrate transport apparatus, or may be an arithmetic processing apparatus provided separately from the substrate transport apparatus.

In the abnormality detection step, if the value related to the amplitude of the measurement data exceeds the first threshold value, it may be determined that there is an abnormality in the transport portion.

In the abnormality detection step, if a trend of increasing is observed in the value related to the amplitude of the measurement data, it may be determined that there is an abnormality in the transport portion.

The value related to the amplitude may be the amount of deviation of the substrate from the rotation center of the rotation stage, which is determined based on the amplitude.

As described above, according to the present disclosure, by using measurement data from an existing measurement portion, an abnormality in the transport portion can be detected with high accuracy without adding a device.

Hereinafter, an example of a substrate transport apparatus and an abnormality detection method according to the present disclosure will be specifically described with reference to the drawings. The above-described constituent elements and steps can be applied to the constituent elements and steps of the substrate transport apparatus and the abnormality detection method of the example described below. The constituent elements and steps of the substrate transport apparatus and the abnormality detection method of the example described below can be modified based on the above description. Also, the matter described below may be applied to the above-described embodiment. Among the constituent elements and steps of the substrate transport apparatus and the abnormality detection method of the example described below, constituent elements and steps that are not essential to the substrate transport apparatus and the abnormality detection method according to the present disclosure may be omitted. Note that the drawings shown below are schematic and do not accurately reflect the shapes or numbers of actual members.

### Embodiment 1

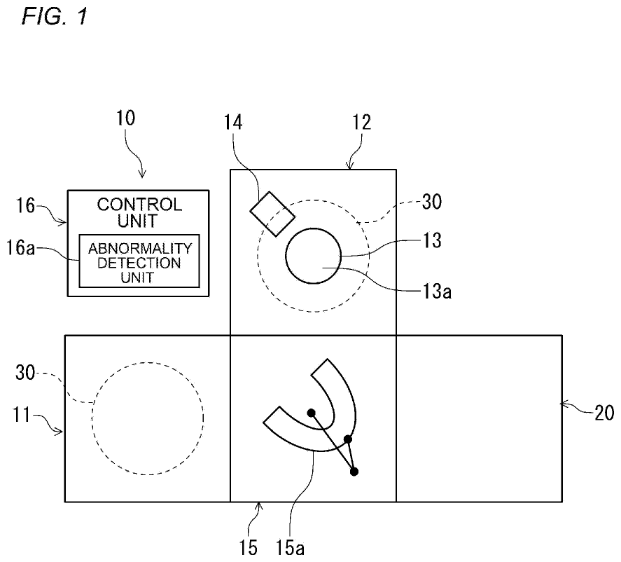

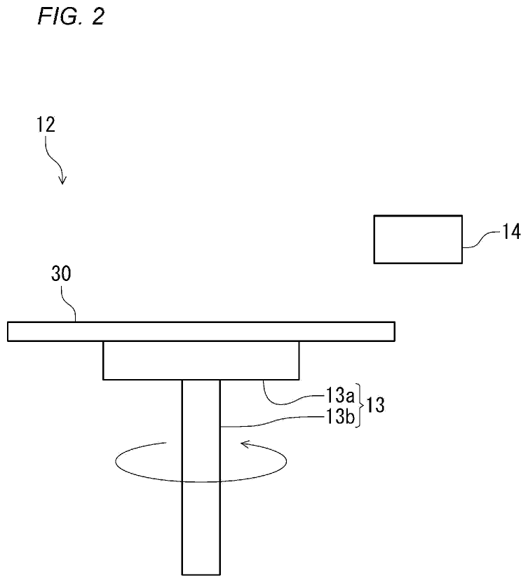

Embodiment 1 of the present disclosure will be described. A substrate transport apparatus 10 of this embodiment is a device for carrying a substrate 30 into and out of a plasma treatment apparatus 20 serving as a substrate processing apparatus. As shown in FIGS. 1 and 2, the substrate transport apparatus 10 includes a substrate storage portion 11, a measurement portion 12, a transport portion 15, and a control unit 16.

The substrate storage portion 11 stores a plurality of substrates 30. The substrates 30 of this embodiment are circular semiconductor substrates, but there is no limitation to this. The substrate storage portion 11 is arranged at a position accessible by the transport portion 15.

The measurement portion 12 includes a rotation stage 13 and a sensor 14. The substrate 30 is placed on the rotation stage 13. The sensor 14 measures the position of an outer edge of the substrate 30 on the rotation stage 13. The measurement data acquired by the sensor 14 is sent to the control unit 16. As shown in FIG. 2, the rotation stage 13 includes a placement portion 13a on which the substrate 30 is placed, and a shaft portion 13b extending downward from the placement portion 13a. The shaft portion 13b is rotatable about a vertical axis by a rotation motor (not shown). Also, the shaft portion 13b is movable in a horizontal direction by a moving mechanism (not shown). By rotating and moving the shaft portion 13b, the position and orientation of the substrate 30 on the placement portion 13a can be adjusted. The measurement portion 12 is arranged at a position accessible by the transport portion 15.

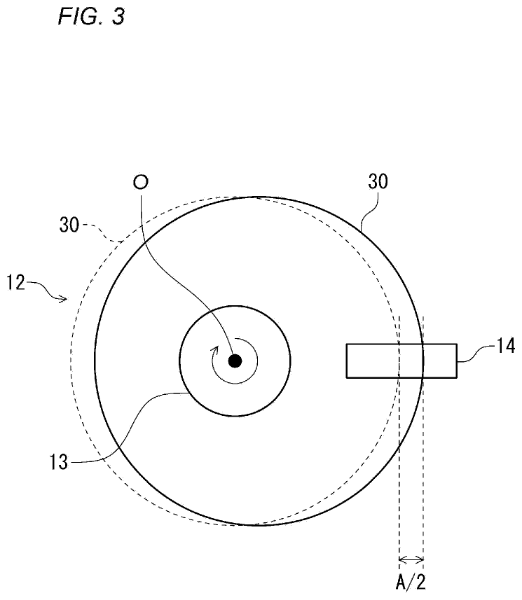

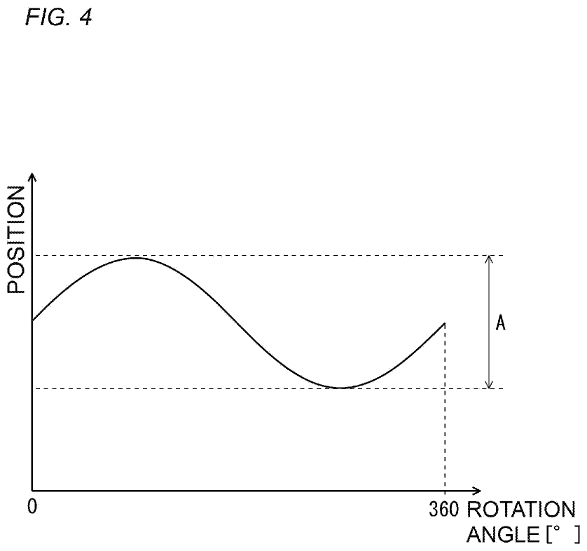

The measurement data acquired by the measurement portion 12 will be briefly described with reference to FIGS. 3 and 4. FIG. 3 is a plan view showing the rotation stage 13, the sensor 14, and the substrate 30 on the rotation stage 13. In the drawing, the substrate 30 with no positional deviation, that is, the substrate 30 whose center coincides with a rotation center O of the rotation stage 13, is indicated by a broken line, and the substrate 30 with positional deviation, that is, the substrate 30 whose center has deviated from the rotation center O of the rotation stage 13, is indicated by a solid line. When the substrate 30 with positional deviation is rotated together with the rotation stage 13, the measurement data indicating the position of the outer edge of the substrate 30 measured by the sensor 14 becomes sinusoidal curve data as shown in FIG. 4. Half (A/2) of an amplitude A of this sinusoidal curve data is the amount of deviation of the substrate 30 from the rotation center O of the rotation stage 13 (hereinafter also referred to as the amount of deviation of the substrate 30).

The transport portion 15 takes out the substrate 30 from the substrate storage portion 11 and places the substrate 30 on the rotation stage 13. The transport portion 15 further takes out the substrate 30 from the measurement portion 12, transports the substrate 30 to the plasma treatment apparatus 20, and transports the substrate 30 after plasma treatment to the substrate storage portion 11. The transport portion 15 includes a transport robot having an end effector 15a that can hold the substrate 30. The end effector 15a may move horizontally and be configured such that the substrate 30 is placed thereon.

The control unit 16 includes an arithmetic device and a storage device storing a program executable by the arithmetic device, and controls each operation of the substrate transport apparatus 10 through execution of the program. The control unit 16 includes an abnormality detection unit 16a that detects an abnormality in the transport portion 15. The abnormality detection unit 16a may be a functional unit realized by the arithmetic device executing the program stored in the storage device.

The abnormality detection unit 16a detects an abnormality in the transport portion 15 based on measurement data (the above-mentioned sinusoidal curve data) acquired by the sensor 14 while the rotation stage 13 is rotated in the measurement portion 12. More specifically, if the amount of deviation of the substrate 30, which serves as the value related to the amplitude of the measurement data, exceeds a first threshold value Th1, the abnormality detection unit 16a determines that there is an abnormality in the transport portion 15. The first threshold value Th1 in this case may be, for example, 2 mm or more.

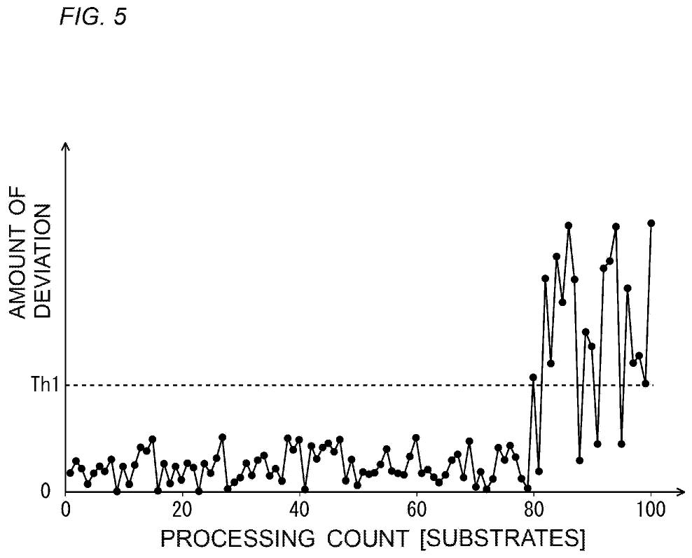

FIG. 5 is an illustrative graph showing a relationship between the amounts of deviation of the substrates 30 (values obtained by multiplying the amplitudes of the measurement data by 0.5) and the processing count of the substrates 30 (the number of substrates 30 transported by the transport portion 15). In this example, when the processing count reaches approximately 80, the amount of deviation of the substrate 30 exceeds the first threshold value Th1, and the abnormality detection unit 16a determines that an abnormality has occurred in the transport portion 15 at this point. On the other hand, if the amount of deviation of the substrate 30 is the first threshold value Th1 or less, the abnormality detection unit 16a may determine that there is no abnormality in the transport portion 15.

### Embodiment 2

Embodiment 2 of the present disclosure will be described. The substrate transport apparatus 10 of this embodiment differs from Embodiment 1 above in the method for detecting an abnormality in the transport portion 15. Hereinafter, differences from Embodiment 1 above will mainly be described.

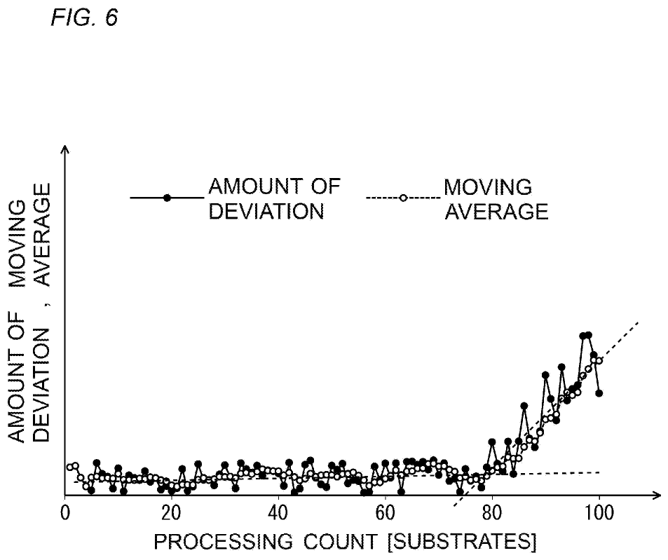

FIG. 6 is an illustrative graph showing a relationship between the amounts of deviation of the substrates 30 (black circles), the moving average of the amounts of deviation (e.g., a 5-term moving average; white circles), and the processing count of the substrates 30. In this example, when the processing count reaches approximately 80, the slope of the moving average (e.g., the slope of the approximate straight line) increases significantly, and the abnormality detection unit 16a determines that an abnormality has occurred in the transport portion 15 at this point. That is, if a trend of increasing is observed in the moving average of the amounts of deviation of the substrates 30, which serves as the value related to the amplitude of the measurement data, the abnormality detection unit 16a of the present embodiment determines that there is an abnormality in the transport portion 15. On the other hand, if a trend of increasing is not observed in the moving average, the abnormality detection unit 16a may determine that there is no abnormality in the transport portion 15.

### Embodiment 3

Embodiment 3 of the present disclosure will be described. The substrate transport apparatus 10 of this embodiment differs from Embodiment 1 above in the method for detecting an abnormality in the transport portion 15. Hereinafter, differences from Embodiment 1 above will mainly be described.

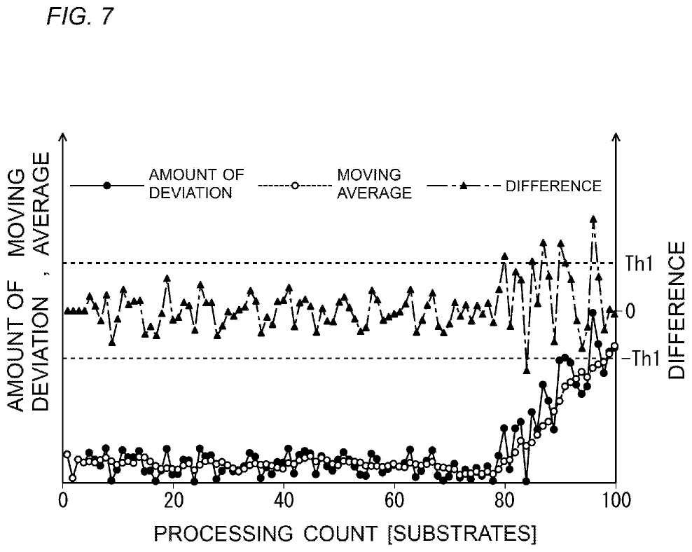

FIG. 7 is an illustrative graph showing a relationship between the amounts of deviation of the substrates 30 (black circles), the moving average of the amounts of deviation (white circles), the difference between the two (triangles), and the processing count of the substrates 30. In this example, when the processing count reaches approximately 80, the absolute value of the difference between the amount of deviation of the substrate 30 and the moving average of the amounts of deviation exceeds the first threshold value Th1, and the abnormality detection unit 16a determines that an abnormality has occurred in the transport portion 15 at this point. The first threshold value Th1 in this case may be, for example, 1 mm or more.

Also, if the above-described absolute value of the difference is less than or equal to the first threshold value Th1, the abnormality detection unit 16a of the present embodiment checks whether or not the moving average of the amount of deviation of the substrate 30 has a trend of increasing that exceeds a criterion. If a trend of increasing that exceeds the criterion is observed, the abnormality detection unit 16a determines that there is an abnormality in the transport portion 15. On the other hand, if the above-described absolute value of the difference is less than or equal to the first threshold value Th1 and a trend of increasing that exceeds the criterion is not observed, the abnormality detection unit 16a may determine that there is no abnormality in the transport portion 15. In this case, the criterion may be that an increase of 0.5 mm or more is observed in the moving average while five substrates 30 are processed.

### Supplementary Notes

The following technique is disclosed by the description of the above embodiments.

### Technique 1

A substrate transport apparatus including:
a substrate storage portion configured to store a substrate;
a measurement portion including a rotation stage on which the substrate is to be placed and a sensor configured to measure a position of an outer edge of the substrate on the rotation stage;
a transport portion configured to take out the substrate from the substrate storage portion and place the substrate on the rotation stage; and
an abnormality detection unit configured to detect an abnormality in the transport portion,
wherein the abnormality detection unit detects an abnormality in the transport portion based on measurement data acquired by the sensor while the rotation stage is rotated in the measurement portion.

### Technique 2

The substrate transport apparatus according to technique 1, in which if a value related to an amplitude of the measurement data exceeds a first threshold value, the abnormality detection unit determines that there is an abnormality in the transport portion.

### Technique 3

The substrate transport apparatus according to technique 1 or 2, in which if a trend of increasing is observed in a value related to an amplitude of the measurement data, the abnormality detection unit determines that there is an abnormality in the transport portion.

### Technique 4

The substrate transport apparatus according to technique 2 or 3, in which the value related to the amplitude is an amount of deviation of the substrate from a rotation center of the rotation stage, the amount of deviation being obtained based on the amplitude.

### Technique 5

An abnormality detection method for detecting an abnormality in a transport portion of a substrate transport apparatus including:
a substrate storage portion configured to store a substrate;
a measurement portion including a rotation stage on which the substrate is to be placed and a sensor configured to measure a position of an outer edge of the substrate on the rotation stage; and
the transport portion configured to take out the substrate from the substrate storage portion and place the substrate on the rotation stage,
the method including an abnormality detection step of detecting an abnormality in the transport portion based on measurement data acquired by the sensor while the rotation stage is rotated in the measurement portion.

### Technique 6

The abnormality detection method according to technique 5, in which in the abnormality detection step, if a value related to an amplitude of the measurement data exceeds a first threshold value, it is determined that there is an abnormality in the transport portion.

### Technique 7

The abnormality detection method according to technique 5 or 6, in which in the abnormality detection step, if a trend of increasing is observed in a value related to an amplitude of the measurement data, it is determined that there is an abnormality in the transport portion.

### Technique 8

The abnormality detection method according to Technique 6 or 7, in which the value related to the amplitude is an amount of deviation of the substrate from a rotation center of the rotation stage, the amount of deviation being obtained based on the amplitude.

### INDUSTRIAL APPLICABILITY

The present disclosure can be used in a substrate transport apparatus and an abnormality detection method.

### REFERENCE NUMERALS

10 Substrate transport apparatus
11 Substrate storage portion
12 Measurement portion
13 Rotation stage
13a Placement portion
13b Shaft portion
14 Sensor
15 Transport portion
15a End effector
16 Control unit
16a Abnormality detection unit
20 Plasma treatment apparatus
30 Substrate
A Amplitude
O Rotation center
Th1 First threshold value

What is claimed is:

1. A substrate transport apparatus comprising:
a substrate storage portion configured to store a substrate;
a measurement portion including a rotation stage on which the substrate is to be placed and a sensor configured to measure a position of an outer edge of the substrate on the rotation stage;
a transport portion configured to take out the substrate from the substrate storage portion and place the substrate on the rotation stage; and
an abnormality detection unit configured to detect an abnormality in the transport portion,
wherein the abnormality detection unit detects an abnormality in the transport portion based on measurement data acquired by the sensor while the rotation stage is rotated in the measurement portion.

2. The substrate transport apparatus according to claim 1, wherein if a value related to an amplitude of the measurement data exceeds a first threshold value, the abnormality detection unit determines that there is an abnormality in the transport portion.

3. The substrate transport apparatus according to claim 1, wherein if a trend of increasing is observed in a value related to an amplitude of the measurement data, the abnormality detection unit determines that there is an abnormality in the transport portion.

4. The substrate transport apparatus according to claim 2, wherein the value related to the amplitude is an amount of deviation of the substrate from a rotation center of the rotation stage, the amount of deviation being obtained based on the amplitude.

5. An abnormality detection method for detecting an abnormality in a transport portion of a substrate transport apparatus including:
a substrate storage portion configured to store a substrate;
a measurement portion including a rotation stage on which the substrate is to be placed and a sensor configured to measure a position of an outer edge of the substrate on the rotation stage; and
the transport portion configured to take out the substrate from the substrate storage portion and place the substrate on the rotation stage,
the method comprising an abnormality detection step of detecting an abnormality in the transport portion based on measurement data acquired by the sensor while the rotation stage is rotated in the measurement portion.

6. The abnormality detection method according to claim 5, wherein in the abnormality detection step, if a value related to an amplitude of the measurement data exceeds a first threshold value, it is determined that there is an abnormality in the transport portion.

7. The abnormality detection method according to claim 5, wherein in the abnormality detection step, if a trend of increasing is observed in a value related to an amplitude of the measurement data, it is determined that there is an abnormality in the transport portion.

8. The abnormality detection method according to claim 6, wherein the value related to the amplitude is an amount of deviation of the substrate from a rotation center of the rotation stage, the amount of deviation being obtained based on the amplitude.
